(19) United States
(12) Patent Application Publication
(10) Pub. No.: US 2010/0253333 A1
(43) Pub. Date: Oct. 7, 2010

(54) DUAL TUNED VOLUME COILS ADAPTED TO PROVIDE AN END RING MODE

(75) Inventors: Zhiyong Zhai, Mayfield Heights, OH (US); Michael A. Morich, Mentor, OH (US); Gordon D. DeMeester, Wickliffe, OH (US)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., Eindhoven (NL)

(21) Appl. No.: 12/742,973

(22) PCT Filed: Dec. 12, 2008
(86) PCT No.: PCT/IB08/55235

§ 371 Date: May 14, 2010

Related U.S. Application Data
(60) Provisional application No. 61/013,333, filed on Dec. 13, 2007.

(51) Int. Cl. G01R 33/44

(52) U.S. Cl. 324/307; 324/318

(57) ABSTRACT

A magnetic resonance coil includes parallel elongate conductive elements (32) arranged to define a cylinder, and end rings (34, 35) disposed at opposite ends of the parallel elongate conductive elements and oriented transverse to the parallel elongate conductive elements. The end rings are configured to support a sinusoidal ¹H or other first species magnetic resonance at a magnetic field strength. The end rings and the parallel elongate conductive elements are configured to cooperatively support a second species birdcage magnetic resonance at the same magnetic field strength, the second species being different from ¹H or other first species.

### FIELD OF THE INVENTION

The following relates to the magnetic resonance arts. The following finds illustrative application to magnetic resonance imaging and spectroscopy, and is described with particular reference thereto. However, the following will find application in other magnetic resonance and radio frequency applications.

### BACKGROUND OF THE INVENTION

Multinuclear magnetic resonance imaging and spectroscopy is of interest for diverse applications, such as metabolic monitoring, diagnosis and clinical monitoring, and so forth. In some multinuclear applications, magnetic resonance excitation, magnetic resonance reception, or both are performed at the ¹H magnetic resonance frequency and at a magnetic resonance frequency of a second nuclear species such as ¹³C, ³¹P, or ²³Na.

To enable simultaneous or concurrent operation at both the ¹H magnetic resonance frequency and at a second species magnetic resonance frequency, two separate, differently-tuned coils can be used. This enables true simultaneous operation at both magnetic resonance frequencies, but has certain disadvantages. The two different magnetic resonance coils occupy valuable bore space. Additionally, the two coils must be spatially aligned with each other, and within the scanner imaging volume, prior to the multinuclear magnetic resonance session.

Another approach is to use a single coil configured to operate at both the ¹H magnetic resonance frequency and the magnetic resonance frequency of a second species (also referred to herein as second species magnetic resonance frequency). A transverse electromagnetic (TEM) volume coil can be dual tuned by using interleaving coil elements (sometimes called coil rungs) for each resonance frequency. A birdcage volume coil can also be double tuned by using interleaving rungs together with radio frequency (RF) traps and a complex end ring arrangement. These approaches can more efficiently utilize the bore space, and by using a single coil there is no need to spatially align two different coils prior to the multinuclear magnetic resonance session. However, some disadvantages arise such as the increased coil complexity and electrical coupling that may occur between the two resonance frequencies.

The following provides new and improved apparatuses and methods which overcome the above-referenced problems and others.

### SUMMARY OF THE INVENTION

In accordance with one aspect, a magnetic resonance coil is disclosed, comprising parallel elongate conductive elements arranged to define a cylinder, and end rings disposed at opposite ends of the parallel elongate conductive elements and oriented transverse to the parallel elongate conductive elements. The end rings are configured to support a sinusoidal ¹H magnetic resonance at a magnetic field strength. The coil is configured to support a second species magnetic resonance at the same magnetic field strength, the second species being different from ¹H. Supporting a particular species magnetic resonance indicates the capability to transmit radio-frequency signals and/or receive magnetic resonance signals at the Larmor frequency of the particular nuclear species at the magnetic field strength.

In accordance with another aspect, a magnetic resonance scanner comprises a main magnet configured to generate a static (B₀) magnetic field (also called main magnetic field), magnetic field gradient coils configured to superimpose selected magnetic field gradients on the static (B₀) magnetic field, and a magnetic resonance coil as set forth in the preceding paragraph.

In accordance with another aspect, a magnetic resonance coil is disclosed, comprising parallel elongate conductive elements arranged to define a cylinder, end rings disposed at opposite ends of the parallel elongate conductive elements and oriented transverse to the parallel elongate conductive elements, and a radio frequency shield proximate at least to the end rings. The end rings, parallel elongate conductive elements, and radio frequency shield are configured to cooperatively support a sinusoidal end ring first species magnetic resonance on the end rings at a magnetic field strength and a second species birdcage magnetic resonance at the same magnetic field strength.

In accordance with another aspect, a magnetic resonance scanner comprises a main magnet configured to generate a static (B₀) magnetic field, magnetic field gradient coils configured to superimpose selected magnetic field gradients on the static (B₀) magnetic field, and a magnetic resonance coil as set forth in the preceding paragraph.

In accordance with another aspect, a magnetic resonance coil is disclosed, comprising parallel elongate conductive elements arranged to define a cylinder, end rings disposed at opposite ends of the parallel elongate conductive elements and oriented transverse to the parallel elongate conductive elements, and radio frequency traps operatively communicating with the elongate conductive elements and tuned to a ¹H magnetic resonance frequency at a magnetic field strength so as to suppress ¹H birdcage magnetic resonance on the magnetic resonance coil at the magnetic field strength.

In accordance with another aspect, a magnetic resonance scanner comprises a main magnet configured to generate a static (B₀) magnetic field, magnetic field gradient coils configured to superimpose selected magnetic field gradients on the static (B₀) magnetic field, and a magnetic resonance coil as set forth in the preceding paragraph.

In accordance with another aspect, a magnetic resonance method is disclosed for concurrently exciting or detecting magnetic resonance of two different species in a common magnetic field using a coil having a pair of end rings and a plurality of transverse elongate conductive elements, the method comprising: operating the end rings in a sinusoidal mode to generate or detect currents flowing at a first species magnetic resonance frequency in the end rings; and concurrently operating the coil in a second mode to generate or detect currents concurrently flowing at a second species magnetic resonance frequency at least in the transverse elongate conductive elements.

One advantage resides in providing a dual-tuned radio frequency coil for multinuclear magnetic resonance operations.

Another advantage resides in more efficient use of bore space.

Another advantage resides in reduced complexity of a dual-tuned radio frequency coil for multinuclear magnetic resonance operations.

Another advantage resides in facilitating simultaneous operation of a dual-tuned coil at ¹H and second species magnetic resonance frequencies.

Still further advantages of the present invention will be appreciated to those of ordinary skill in the art upon reading and understand the following detailed description.

### BRIEF DESCRIPTION OF THE DRAWINGS

These and other aspects will be described in detail hereinafter, by way of example, on the basis of the following embodiments, with reference to the accompanying drawings, wherein:

FIG. 1 diagrammatically shows a system for performing multinuclear magnetic resonance imaging or spectroscopy;

FIG. 2 diagrammatically shows a dual-tuned radio frequency coil suitable for use in the system of FIG. 1;

FIG. 3 plots sinusoidal resonance frequency versus end ring radius for an end ring modeled as a continuous unshielded circular annular conductor without intervening capacitance or inductance elements;

FIG. 4 diagrammatically shows an electrical schematic for a suitable ¹H radio frequency trap suitable for use in the coil of FIG. 2; and

FIG. 5 diagrammatically shows a dual-tuned radio frequency coil suitable for use in the system of FIG. 1 and having a different radio frequency shield or screen configuration as compared with the coil of FIG. 2.

### DETAILED DESCRIPTION OF EMBODIMENTS

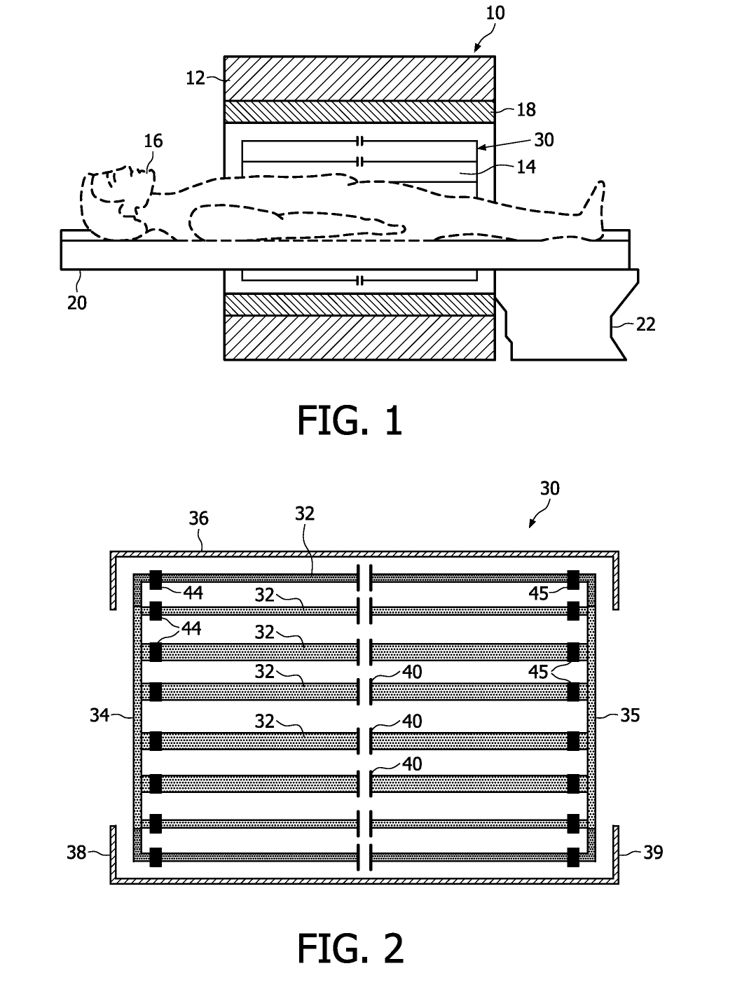

With reference to FIG. 1, a magnetic resonance scanner 10 includes a main magnet 12 generating a static (B₀) magnetic field in an examination region 14 in which is disposed a subject 16 (shown in dashed lines in FIG. 1). The illustrated magnetic resonance scanner 10 is a horizontal bore-type scanner shown in cross-section to reveal selected components for illustration. The magnetic resonance scanner 10 is a high-field scanner in which the main magnet 12 produces the static (B₀) magnetic field in the examination region 14 at a magnetic field strength greater than 3 Tesla, and in some embodiments greater than or about 5 Tesla. In some embodiments, the main magnet 12 produces a static (B₀) magnetic field in the examination region 14 at a magnetic field strength of 7 Tesla. Higher magnetic field strengths are also contemplated.

The magnetic resonance scanner 10 also includes magnetic field gradient coils 18 that superimpose selected magnetic field gradients on the static (B₀) magnetic field to perform various tasks such as spatially restricting magnetic resonance excitation, spatially encoding magnetic resonance frequency and/or phase, spoiling magnetic resonance, or so forth. Optionally, the magnetic resonance scanner may include other elements not shown in FIG. 1, such as a bore liner, active coil or passive ferromagnetic shims, or so forth. The subject 16 is suitably prepared by being placed on a movable subject support 20 which is then inserted along with the supported subject 16 into the illustrated position for magnetic resonance acquisition. For example, the subject support 20 may be a pallet or table that is initially disposed on a couch 22 adjacent the magnetic resonance scanner 10, the subject 16 placed onto the support 20 and then slidably transferred from the couch 22 into the bore of the magnetic resonance scanner 10.

With continuing reference to FIG. 1 and with further reference to FIG. 2, a magnetic resonance coil 30 is provided to excite and receive magnetic resonance. In multinuclear magnetic resonance, two or more nuclear species are of interest, such as two or more nuclear species selected from a group consisting of ¹H, ¹³C, ³¹P, and ²³Na. In some multinuclear magnetic resonance applications, two species are of interest, namely ¹H and a second nuclear species other than ¹H, such as ¹³C, ³¹P, ²³Na, or so forth.

The magnetic resonance coil 30 has a birdcage configuration including a plurality of parallel elongate conductive elements 32 (sometimes called “rungs” 32 herein) arranged to define a cylinder, and end rings 34, 35 disposed at opposite ends of the parallel elongate conductive elements 32 and oriented transverse to the parallel elongate conductive elements 32. A generally cylindrical radio frequency shield 36 surrounds the parallel elongate conductive rungs 32 and generally coaxial with the cylinder defined by the parallel elongate conductive elements 32. The radio frequency shield 36 includes annular flanges 38, 39 disposed parallel with and proximate to respective end rings 34, 35 at opposite ends of the parallel rungs 32. The illustrated magnetic resonance coil 30 is a whole-body coil, sized to fit coaxially into the cylindrical bore of the illustrated horizontal bore scanner 10; however, the magnetic resonance coil can also be sized as a head coil to fit over the head of the subject 16, or sized as a limb coil to fit over an arm or leg of the subject 16, or so forth.

The magnetic resonance coil 30 is a dual-tuned radio frequency coil supporting end ring resonance at a first magnetic resonance frequency of a first nuclear species, and birdcage magnetic resonance at a second magnetic resonance frequency of a second nuclear species different from the first nuclear species. In the following, the end ring resonance is assumed to correspond to the ¹H magnetic resonance frequency at a magnetic field strength of a static (B₀) magnetic field generated by the main magnet 12, while the birdcage resonance is assumed to correspond to a second species magnetic resonance frequency at the same magnetic field strength, where the second species magnetic resonance frequency is different from the ¹H magnetic resonance frequency. However, it is also contemplated for the end ring resonance to correspond to the magnetic resonance frequency of another nuclear species besides ¹H at a magnetic field strength.

The birdcage coil 30 resonates as a volume resonator with a birdcage resonance at the second species magnetic resonance frequency. Optionally, the birdcage magnetic resonance frequency is tuned by suitable tuning elements in the elongate conductive elements or rungs, such as illustrated by discrete rung capacitances 40, or by distributed capacitance in the rungs 32, end rings 34, 35, or both, or by discrete or distributed inductances, or so forth. The use of multiple tuning capacitances, or distributed capacitance, can be advantageous in order to reduce high localized electric fields in the vicinity of the tuning capacitors. In some embodiments, geometrical or material aspects of the shielding 36 and annular flanges 38, 39 such as but not limited to material conductance, spacing from the rungs 32, thickness of the mesh or screen material of the shielding, or so forth also affects the birdcage magnetic resonance frequency.

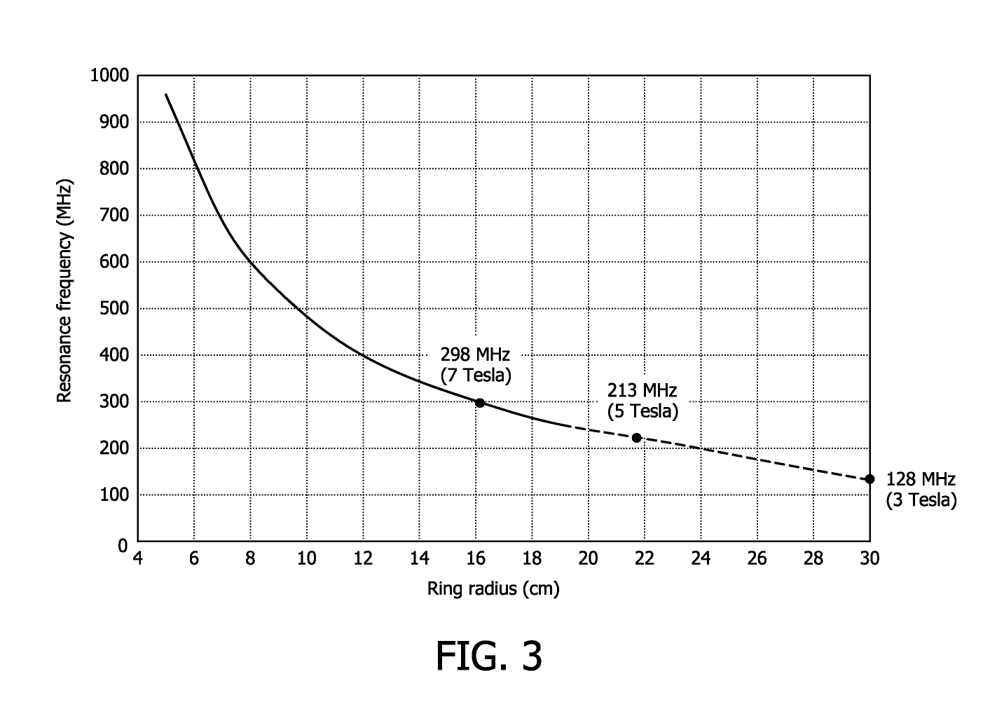

With brief reference to FIG. 3, the end rings 34, 35 (shown in FIG. 2) are also configured to resonate sinusoidally at the ¹H magnetic resonance frequency. FIG. 3 plots sinusoidal resonance frequency versus end ring radius for an end ring modeled as a continuous unshielded circular annular conductor without intervening capacitance or inductance elements. (As used herein, the term “sinusoidal resonance” and the like is intended to encompass sinusoidal resonance irrespective of phase, and encompasses, for example, what might also be termed “cosinusoidal resonance” depending upon the reference phase). The plot of FIG. 3 was generated by electromagnetic simulation for radii up to 20 cm and the curve is extrapolated to 30 cm radius. It is recognized herein that for high-field magnetic resonance and for an end ring 34, 35 of sufficiently large radius, the sinusoidal mode circulates at a useful frequency range matching certain magnetic resonance frequencies of interest. For instance, the ¹H magnetic resonance frequency is 298 MHz in a static (B₀) magnetic field of 7 Tesla. As indicated in FIG. 3, the sinusoidal resonance of the end rings 34, 35 having reasonable radii of about 15 centimeters, which is a typical radius for a human head coil, is close to the ¹H magnetic resonance frequency at a magnetic field strength of 7 Tesla. Taking into account the effect of the cylindrical shield 36 and adjacent shielding flanges 38, 39, the resonance frequency of the sinusoidal mode can be closely matched to 298 MHz in a head coil configuration. The shielding 36, 38, 39 also advantageously sharpens the resonance quality (Q-factor) of the sinusoidal resonance supported by the end rings 34, 35.

With continuing reference to FIGS. 2 and 3, it can be seen that when the end rings 34, 35 have a radius of between about 10 centimeters and about 20 centimeters, the resonance frequency for the sinusoidal mode is between about 200 MHz and about 500 MHz (taking into account the effects of the shielding 36, 38, 39, and allowing for optional tuning by adding reactance elements such as capacitances or capacitive gaps in the annular conductor). These resonance frequencies span the magnetic resonance frequencies of some of the nuclear species of interest at high magnetic field. FIG. 3 also extrapolates the calculated curve out to 128 MHz (extrapolation indicated by dashed lines), corresponding to a static magnetic field of about 3 Tesla. The extrapolation indicates that unshielded and untuned end rings with diameters of about 60 centimeters (30 centimeters radius) to 70 centimeters (35 centimeters radius), which is the typical diameter for a whole body radio frequency coil, support sinusoidal resonance at about the ¹H proton magnetic resonance frequency for a magnetic field strength of 3 Tesla.

The plot of FIG. 3 is illustrative for unshielded continuous annular conductors. It is to be understood that the sinusoidal resonance frequency supported by end rings 34, 35 of a given diameter can be adjusted over a substantial frequency range by inclusion of tuning elements, by the configuration of the shielding 36, 38, 39, by the thickness and width of the end rings 34, 35, and so forth. The sinusoidal resonance frequency of the end rings 34, 35 can be tuned to the ¹H magnetic resonance frequency or to another magnetic resonance frequency of interest by adding lumped or distributed capacitances or inductances along the end rings, by varying parameters such as the radius, the thickness or other cross-sectional dimensions of the end rings 34, 35, by adjusting the shielding 36, 38, 39, by adding reactance elements such as capacitances or capacitive gaps in the end rings 34, 35, by adding dielectric materials between the end ring 34 and flange 38, and/or end ring 35 and flange 39, or by various combinations of such adjustments. Moreover, it is recognized herein that at higher magnetic field, the spatial uniformity provided by sinusoidal resonance in the end rings 34, 35 is largely determined by the dielectric and conductive characteristics of the subject 16 or other loading of the coil 30; hence, at static B₀ magnetic field values greater than or about 3 Tesla, the relatively large unloaded non-uniformity of the B₁ field generated by the sinusoidal mode is acceptable.

With reference back to FIG. 2, the end rings 34, 35 are connected to the rungs 32. The rungs 32 interfere with the sinusoidal end ring resonance. To reduce or eliminate such interference, radio frequency traps 44, 45 are suitably disposed with or integrated into the rungs 32. The traps 44, 45 are RF filters designed to present a blocking high impedance at the sinusoidal resonance frequency supported by the end rings 34, 35, while having almost no effect on the birdcage resonance at a second frequency different from the resonance frequency supported by the end rings 34, 35. The traps 44, 45 virtually isolate the end rings 34, 35 from the rungs 32 at the end ring resonance. For example, if the designed magnetic field strength is 7 Tesla and end rings are designed to support the ¹H magnetic resonance frequency at 7 Tesla (i.e., 298 MHz), then the radio frequency traps 44, 45 are suitably designed as notch filters to block the 298 MHz resonance frequency. As illustrated in FIG. 2, in some embodiments the radio frequency traps 44, 45 are disposed at ends of the rungs 32 close to the end rings 34, 35.

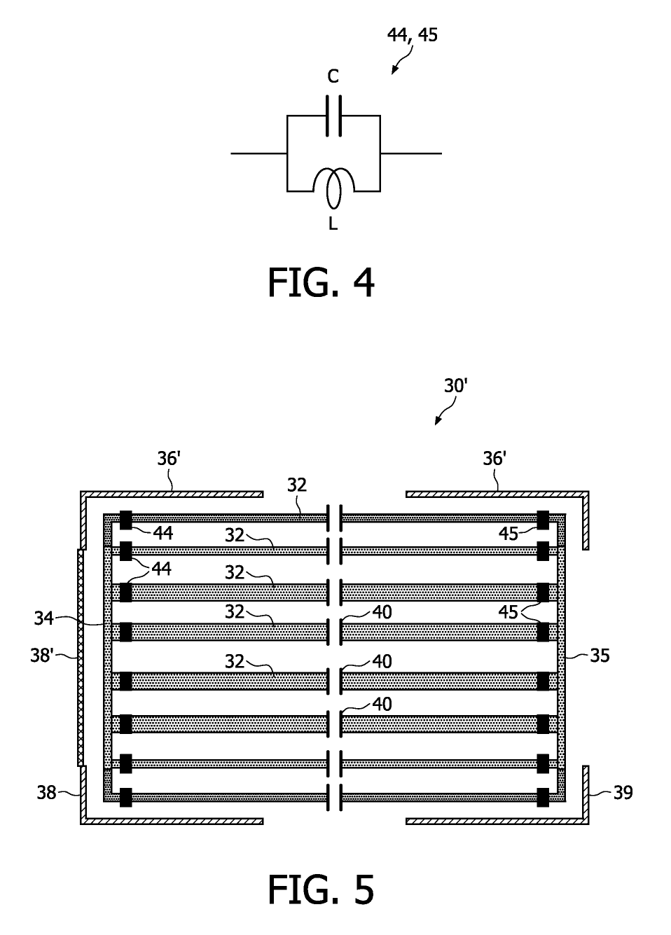

With reference to FIG. 4, in some embodiments the radio frequency traps 44, 45 are parallel LC tank circuits (where L denotes inductance and C denotes capacitance) for which the impedance maximizes at a frequency of

$$\frac{1}{2 \cdot π \cdot \sqrt{LC}} .$$

Other radio frequency trap configurations are also contemplated. With the traps 44, 45 tuned to the ¹H magnetic resonance frequency, the traps 44, 45 block current flow at the ¹H magnetic resonance frequency but allow current flow at other frequencies such as at the second species magnetic resonance frequency at which the birdcage resonance mode operates.

With reference to FIG. 5, a modified coil 30′ includes the rungs 32 and end-rings 34, 35. However, the shielding 36, 38, 39 of the coil of FIG. 2 is replaced in the modified coil 30′ of FIG. 5 by an open shield 36′ that does not include shielding material in a central region. In this case, the cylindrical shield 36′ is divided into two separated parts by the open central region. At the birdcage resonance frequency, the birdcage coil behavior is close to an unshielded birdcage, which substantially improves coil sensitivity. The shielding further includes the flanges 38, 39. Optionally, one flange, such as the flange 38, may be replaced by an end cap 38′. Although not shown, such replacement of a flange by an end cap can also be made in the coil 30 of FIG. 2. The open shield 36′ advantageously increases coil sensitivity for the second species (non-¹H) magnetic resonance, because radiation loss at the second species magnetic resonance frequency is not significant. The open shield 36′ does not adversely affect the coil sensitivity for the ¹H magnetic resonance because the sinusoidal resonance coupling with the ¹H magnetic resonance is supported by the end rings 34, 35 which are relatively far away from the open central region of the open shield 36′.

Having described some illustrative coil embodiments 30, 30′, some further illustrative implementations are described by way of further example.

The end rings 34, 35 are suitably tuned to a sinusoidal resonance mode at the ¹H magnetic resonance frequency by adjustable ring capacitors (not shown) or other elements affecting the sinusoidal resonance of the end rings 34, 35. In some embodiments in which a desired diameter of the ring is pre-determined, individual inductors in series with ring capacitors can be used to tune the end rings 34, 35 to the sinusoidal resonance mode at the ¹H magnetic resonance frequency. At the ¹H magnetic resonance frequency, the traps 44, 45 in the coil rungs 32 have high impedance which suppresses the current from flowing to the coil rungs 32. In the illustrated embodiments, the traps 44, 45 are located on or with the rungs 32 near the connections to the respective end rings 34, 35. Thus the two end rings 34, 35 can be fed in quadrature for transmitting and receiving of ¹H signal. At the second species (non-¹H) frequency, the traps 44, 45 function approximately as a short circuit, which allow the current at the second species magnetic resonance frequency to flow between the end rings 34, 35 and the rungs 32 in accordance with the birdcage resonance mode. The coil 30, 30′ thus defines a shielded band-pass birdcage coil resonant at the second species magnetic resonance frequency. The birdcage resonance can be tuned to the desired second species magnetic resonance frequency by adjusting values of the rung capacitors 40. Optionally, the birdcage resonance frequency can also be adjusted by adjusting the diameters of the end rings 34, 35, adjusting the end ring positions along the rungs 32, by including tuning end ring elements such as capacitors or inductors, or so forth. Where a parameter such as an end ring tuning capacitor value affects both the sinusoidal and birdcage resonance frequencies, the parameter values can be selected by iterative adjustment in conjunction with suitable electromagnetic modeling to tune both the sinusoidal and birdcage resonance frequencies together.

To further illustrate advantages of the dual-tuned volume coils disclosed herein as compared with a TEM multi-nuclear coil, the coil 30 of FIG. 1 was modeled as a head-size transmit/receive (T/R) coil with a diameter of 30 cm and rung lengths of 21 cm. The cylindrical shield diameter was modeled as 35 cm and the shield length was modeled as 23 cm. Twelve rungs 32 were included in the coil model. The two end rings 34, 35 were modeled as flat annular rings with inner diameter of 28 cm and outer diameter of 31 cm. The end rings 34, 35 were tuned to the ¹H magnetic resonance frequency of 298 MHz (corresponding to a magnetic field strength of 7 Tesla), and the shielded birdcage coil was tuned to the ³¹P frequency of 120.7 MHz for the same 7 Tesla magnetic field strength. For comparison, a 12-element TEM coil was modeled with the same size as the birdcage coil, and tuned to the same ³¹P frequency of 120.7 MHz. A 20 cm-diameter spherical phantom (conductivity □=0.855 S/m, relative permittivity [symbol] =80) was used to model loading of both coil models. In the model, the coil elements and the shield structure were separated by air.

The two end rings were modeled as operated in a two-port drive in quadrature at 298 MHz, where one port was fed in one end ring and another port with opposite voltage but 90-degree out of phase is fed in the other end ring. The birdcage coil was two-port driven in quadrature in the middle of two rungs at 120.7 MHz. The comparative TEM coil was also modeled as operated in a two-port drive in quadrature, across capacitors at the ends. The |B₁⁺|-field (radio-frequency transmit field) in three center slices of the sphere phantom were calculated at both resonance frequencies, 298 MHz and 120.7 MHz. The transmit efficiency was calculated as

$$η = \frac{{\vert {B}_{1}^{+} \vert}_{ave}}{\sqrt{{P}_{abs}}} ,$$

where |B₁⁺|ₐᵥₑ is the average |B₁⁺|-field in the center transverse slice of the sphere phantom and P_{abs} is the total absorbed power of the phantom. The coil sensitivity was calculated as |B₁⁺|ₐᵥₑ per unit current in the coil rungs (or ring in the case of end ring only resonance mode).

The |B₁⁺|-field uniformity at the ¹H magnetic resonance frequency was found to be dominated by the dielectric effect of the phantom material, which is comparable to a T/R birdcage or TEM volume coil. The |B₁⁺|-field uniformity at the ³¹P magnetic resonance frequency was found to be relatively uniform and similar to that of a TEM coil. Table 1 lists the calculated transmit efficiency and maximum local SAR (10 g phantom material averaged SAR) at |B₁⁺|ₐᵥₑ=1□ T. The coil sensitivity for the modeled duakuned volume coil and for the comparative 12-element TEM volume coil at 120.7 MHz is also given in Table 1. It is seen that, at 120.7 MHz, the birdcage coil has about the same transmit efficiency as the TEM coil, but has less local SAR and substantially higher coil sensitivity. Furthermore, the birdcage coil has a less complex structure with only twelve rungs, whereas the dual tuned TEM volume coil employed a more complicated structure of twenty-four elements, of which twelve elements provided resonance at the ¹H magnetic resonance frequency and another twelve interleaved elements provided resonance at the ³¹P magnetic resonance frequency.

TABLE 1

| | Dual-tuned volume coil | | | | Comparative | |
|---|---|---|---|---|---|---|
| | Two | | | | 12-element | |
| | end rings at | | Birdcage at | | TEM | |
| Volume coil | 298 MHz | | 120.7 MHz | | at 120.7 MHz | |
| Transmit efficiency | 0.5□ | T/W^{1/2} | 0.8□ | T/W^{1/2} | 0.8□ | T/W^{1/2} |
| Max. local SAR at | 2.5 | W/kg | 0.6 | W/kg | 0.8 | W/kg |
| \|B₁⁺\|ₐᵥₑ = 1□ T | | | | | | |

| | | | | | |
|---|---|---|---|---|---|
| Coil sensitivity | — | 2.5□ | T/A | 1.4□ | T/A |

Another advantage of the dual-tuned volume coil employing sinusoidal end-ring and birdcage resonances is that the coil sensitivity at the birdcage resonance (i.e., second species magnetic resonance) can be enhanced by opening the shield in the middle, as shown in FIG. 5. The open shield 36′ of FIG. 5 is not compatible with a TEM coil because it would not support the TEM resonance mode.

A modeling example of the modified coil 30′ of FIG. 5 is also presented. The same coil model as previously described was again used, except that the cylindrical shield was opened in the middle as shown in FIG. 5, with the central open region being a 10 cm wide gap. The optional end cap 38′ was not included in the modeling. Table 2 lists the calculated results for the model with a closed shield (as in FIG. 2) and with a partially open shield (as in FIG. 5). As seen in Table 2, the coil sensitivity is increased from 2.5□ T/A for the coil with the closed shield to 6.4□ T/A for the coil with the open shield having the 10 cm gap. The coil sensitivity is more than doubled by having the 10 cm gap. The high coil sensitivity of the open-shielded coil is not readily attainable in dual-tuned coils for 7 Tesla operation that are shielded at both the ¹H and second species magnetic resonance frequencies. While providing a shield for the ¹H coil resonance is advantageous at 7 Tesla to reduce radiation loss, providing a shield for the second species (i.e., non-¹H) coil resonance is not advantageous, because most non-¹H magnetic resonance frequencies are substantially lower than the ¹H magnetic resonance frequency (for the same magnetic field strength) and accordingly exhibit substantially lower radiation loss. The partial shielding of the coil of FIG. 5 is enabled by the combination of sinusoidal end ring resonance for the ¹H magnetic resonance coupling and birdcage resonance for the second species magnetic resonance coupling.

TABLE 2

| | Two end rings | | Birdcage | |
|---|---|---|---|---|
| | at 298 MHz | | at 120.7 MHz | |
| Transmit efficiency | 0.5□ | T/W^{1/2} | 0.8□ | T/W^{1/2} |
| Max. local SAR at | 2.8 | W/kg | 0.6 | W/kg |
| \|B₁⁺\|ₐᵥₑ = 1□ T | | | | |

| | | | |
|---|---|---|---|
| Coil sensitivity | — | 6.4□ | T/A |

Modeling was also performed to estimate peak electric field distributions for the dual-tuned (sinusoidal end ring/birdcage) coil 30′ of FIG. 5 having a 10 cm gap in the shield 36′. The gap in the shield 36′ was found to result in leakage of electromagnetic field outside the coil which can increase radiation losses. However, this effect is not expected to be problematic because a typical magnetic resonance scanner includes another body-sized shield which could help contain the power loss. Moreover, radiation loss for the 128 MHz ¹H magnetic resonance at 3 Tesla is not problematic for birdcage type head T/R coils. At higher magnetic field strengths, a design tradeoff can be made between radiation losses (suppressed by reducing the gap of the shield 36′) and coil sensitivity to the second species magnetic resonance (enhanced by increasing the gap of the shield 36′).

In the illustrated embodiments, the coil has a birdcage configuration in which the end rings 34, 35 are operatively coupled with the parallel elongate conductive elements 32 to support the second species birdcage magnetic resonance. This allows the option of using either the closed radio frequency shield 36 or the open radio frequency shield 36′. It is also contemplated to operatively connect the parallel elongate conductive elements with the shield, which in such embodiments is a closed shield similar to the radio frequency shield 36, such that the second species resonance is supported in a TEM mode while the end rings support only the sinusoidal first species (e.g., ¹H) magnetic resonance. In such embodiments, the radio frequency traps blocking ¹H (or other first species) resonance on the parallel elongate conductive elements 32 suppress inductive coupling at the ¹H frequency.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A magnetic resonance coil comprising:
parallel elongate conductive elements arranged to define a cylinder; and
end rings disposed at opposite ends of the parallel elongate conductive elements and oriented transverse to the parallel elongate conductive elements;
the end rings being configured to support a sinusoidal ¹H magnetic resonance at a magnetic field strength; and
the coil being further configured to support a second species magnetic resonance at the same magnetic field strength, the second species being different from ¹H.

2. The magnetic resonance coil as set forth in claim 1, wherein the end rings and the parallel elongate conductive elements cooperate to support the second species magnetic resonance as a birdcage second species magnetic resonance at the magnetic field strength.

3. The magnetic resonance coil as set forth in claim 1, wherein the parallel elongate conductive elements include radio frequency trap elements configured to substantially suppress ¹H magnetic resonance on the parallel elongate conductive elements at the magnetic field strength.

4. The magnetic resonance coil as set forth in claim 1, further comprising:
one or more radio frequency shield portions arranged proximate to at least the end rings, the one or more radio frequency shield portions cooperating with the end rings to configure the end rings to support the sinusoidal ¹H magnetic resonance at the magnetic field strength.

5. The magnetic resonance coil as set forth in claim 4, wherein the one or more radio frequency shield portions comprise:
at least one of a shield flange portion and a shield endcap portion arranged at each end of the parallel elongate conductive elements to shield a proximate one of the end rings.

6. The magnetic resonance coil as set forth in claim 4, wherein the one or more radio frequency shield portions comprise:
a cylindrical radio frequency shield further including at least one of a shield flange portion and a shield endcap portion arranged at each end of the parallel elongate conductive elements to shield a proximate one of the end rings.

7. The magnetic resonance coil as set forth in claim 6, wherein:
the end rings and the parallel elongate conductive elements cooperate to support the second species magnetic resonance as a birdcage second species magnetic resonance at the magnetic field strength; and
the cylindrical radio frequency shield has a central open region.

8. A magnetic resonance scanner comprising:
a main magnet configured to generate a static (B₀) magnetic field;
magnetic field gradient coils configured to superimpose selected magnetic field gradients on the static (B₀) magnetic field; and
a magnetic resonance coil as set forth in claim 1.

9. A magnetic resonance coil comprising:
parallel elongate conductive elements arranged to define a cylinder;
end rings disposed at opposite ends of the parallel elongate conductive elements and oriented transverse to the parallel elongate conductive elements; and
a radio frequency shield proximate at least to the end rings;
the end rings, parallel elongate conductive elements, and radio frequency shield being configured to cooperatively support a sinusoidal end ring first species magnetic resonance on the end rings at a magnetic field strength and a second species birdcage magnetic resonance at the same magnetic field strength.

10. The magnetic resonance coil as set forth in claim 9, wherein the parallel elongate conductive elements include radio frequency traps tuned to block the first species magnetic resonance frequency at the magnetic field strength.

11. The magnetic resonance coil as set forth in claim 9, wherein the radio frequency shield comprises:
a flange or endcap disposed proximate to a first end ring of the end rings; and
a flange or endcap disposed proximate to a second end ring of the end rings.

12. The magnetic resonance coil as set forth in claim 11, wherein the radio frequency shield further comprises:
a cylindrical radio frequency shield surrounding the parallel elongate conductive elements and coaxial with the cylinder defined by the parallel elongate conductive elements.

13. The magnetic resonance coil as set forth in claim 12, wherein the cylindrical radio frequency shield has an open central region.

14. A magnetic resonance method for concurrently exciting or detecting magnetic resonance of two different species in a common magnetic field using a coil having a pair of end rings and a plurality of transverse elongate conductive elements, the method comprising:
operating the end rings in a sinusoidal mode to generate or detect currents flowing at a first species magnetic resonance frequency in the end rings; and
concurrently operating the coil in a second mode to generate or detect currents concurrently flowing at a second species magnetic resonance frequency at least in the transverse elongate conductive elements.

15. The magnetic resonance method as set forth in claim 14, wherein the operating of the coil in the second mode comprises:
operating the coil in a birdcage mode to generate or detect currents concurrently flowing at the second species magnetic resonance frequency in the transverse elongate conductive elements and in the end rings.
